(19) United States
(12) Patent Application Publication
(10) Pub. No.: US 2026/0092679 A1
(43) Pub. Date: Apr. 2, 2026

(54) APPARATUS AND METHOD FOR HYDROGEN FUELING SIMULATION IN RTR-HFP

(71) Applicant: MIRAE EHS-CODE RESEARCH INSTITUTE, Gwangmyeong-si (KR)

(72) Inventor: Chung Keun CHAE, Seoul (KR)

(73) Assignee: MIRAE EHS-CODE RESEARCH INSTITUTE, Gwangmyeong-si (KR)

(21) Appl. No.: 19/342,456

(22) Filed: Sep. 26, 2025

(30) Foreign Application Priority Data
Sep. 27, 2024 (KR) 10-2024-0131727
Oct. 28, 2024 (KR) 10-2024-0148601
Dec. 24, 2024 (KR) 10-2024-0195613

(51) Int. Cl. F17C 5/00; G06F 30/28

(52) U.S. Cl. CPC F17C 5/007; G06F 30/28; F17C 2221/012; F17C 2250/034; F17C 2250/0426; F17C 2250/043; F17C 2250/0439; F17C 2250/0443; F17C 2250/0694; F17C 2265/065; F17C 2270/0168

(57) ABSTRACT

The method for performing a hydrogen fueling simulation comprises obtaining information on at least one of a capacity of a largest hydrogen tank equipped for hydrogen fueling in a real-case scenario, a total capacity of hydrogen tanks, a supply fuel temperature of a fueling line, a supply fuel pressure, and a pressure of a hydrogen tank; extracting, from a predefined lookup table, a first pressure loss coefficient corresponding to a fueling line pressure loss coefficient that satisfies a predetermined condition in a reference case and a second pressure loss coefficient corresponding to a pressure loss coefficient for SAE test configuration in H2Fills, based on the obtained information; calculating an average density in the fueling line; calculating a third pressure loss coefficient based on the average density, a measured mass flow rate, and a pressure difference between a fuel supply pressure and a hydrogen tank pressure in the fueling line.

This application claims the benefit of Korean Patent Provisional Application No. 10-2024-0131727, filed on Sep. 27, 2024, Korean Patent Provisional Application No. 10-2024-0148601, filed on Oct. 28, 2024, and Korean Patent Application No. 10-2024-0195613, filed on Dec. 24, 2024, which is hereby incorporated by reference as if fully set forth herein.

### BACKGROUND OF THE INVENTION

### Field of the Invention

The present invention relates to a method and apparatus for hydrogen charging simulation, and more specifically, to a method and apparatus for hydrogen fueling simulation in RTR-HFP.

### Discussion of the Related Art

A hydrogen vehicle uses hydrogen as a fuel source. It either burns hydrogen in an internal combustion engine to drive an electric motor or reacts hydrogen with oxygen in a fuel cell, converting the chemical energy of hydrogen into mechanical energy. Hydrogen is used to supply transportation fuel. However, hydrogen fuel is rapidly charged at high pressure, which makes it more dangerous than refueling. Furthermore, heat generation due to compression and the Joule-Thomson effect makes full charging difficult. Therefore, various countries have developed hydrogen charging protocols. Among these, many studies have focused on protocols that utilize lookup tables for pressure rise rates and target pressures based on charging parameters (Hydrogen Fueling Protocols).

The SAE (Society of Automotive Engineers) J2601 Hydrogen Fueling Protocol (HFP), established in 2010, utilizes a method that utilizes numerous pre-set tables and calculation formulas, parameters, and coefficients, based on simulations based on thermodynamic models, to perform fueling (or charging).

Recently, the spread of hydrogen fuel cell vehicles has expanded, and the commercialization of large-scale mobility (e.g., buses, trucks, ships) to address global warming has been rapidly advancing. In particular, the scale and applications of large-scale mobility vehicles vary significantly, making it structurally impossible to accommodate their compressed hydrogen storage system (CHSS) capacity, charging speed, nominal working pressure, and application restrictions within the existing HFP. Therefore, the introduction of a new HFP is necessary. In particular, there is an urgent need for a new HFP that ensures versatility across a wide range of applications and accommodates high capacity, high velocity, and high efficiency. A new HFP is needed to dramatically improve the limitations of the existing HFP's scope and application methods, as well as its low efficiency.

Existing hydrogen fueling protocol requires numerous assumptions and criteria to simulate real hydrogen fueling protocols, as they require hydrogen fuel supply simulations during the design phase. However, no research has yet been conducted to address these issues.

### SUMMARY OF THE INVENTION

It is an object of the present invention to provide method for performing hydrogen fueling simulation using a Real-Time Response Hydrogen Fueling Protocol (RTR-HFP).

It is another object of the present invention to provide apparatus for performing hydrogen fueling simulation using a Real-Time Response Hydrogen Fueling Protocol (RTR-HFP).

Objects of the present invention are not limited to the aforementioned objects, and other unmentioned objects will be clearly understood by those skilled in the art based on the following description.

In accordance with an aspect of the present invention, the above and other objects can be accomplished by the provision of a method for performing a hydrogen fueling simulation in a Real-Time Response Hydrogen fueling Protocol comprises obtaining information on at least one of a capacity of a largest hydrogen tank equipped for hydrogen fueling in a real-case scenario, a total capacity of hydrogen tanks, a supply fuel temperature of a fueling line, a supply fuel pressure, and a pressure of a hydrogen tank; extracting, from a predefined lookup table, a first pressure loss coefficient corresponding to a fueling line pressure loss coefficient that satisfies a predetermined condition in a reference case and a second pressure loss coefficient corresponding to a pressure loss coefficient for SAE test configuration in H2Fills, based on the obtained information; calculating an average density in the fueling line; calculating a third pressure loss coefficient based on the average density, a measured mass flow rate, and a pressure difference between a fuel supply pressure and a hydrogen tank pressure in the fueling line; and calculating a pressure loss coefficient of a virtual fueling line in an RTR simulator based on the first pressure loss coefficient, second pressure loss coefficient, and the third pressure loss coefficient.

The method further comprises extracting, from the predefined lookup table, an inner diameter of a reference fueling line that satisfies a predetermined condition in the reference case; and calculating an inner diameter of the virtual fueling line based on the calculated pressure loss coefficient of the virtual fueling line, the extracted first pressure loss coefficient, and the extracted inner diameter of the reference fueling line.

The predefined lookup table includes: a first type lookup table including pressure loss coefficients (K_FL_Ref) that satisfy a predetermined condition in the reference case according to an ambient air temperature and the supply fuel temperature for each capacity value of the largest hydrogen tank; a second type lookup table including pressure loss coefficients (K_FL_H2F) for the SAE test configuration in the H2Fills; and a third type lookup table including an inner diameter (d_FL_Ref) of the reference fueling line that satisfies the predetermined condition in the reference case.

The measured mass flow rate in the fueling line is measured by a flow meter installed in a hydrogen refueling station (HRS) in the real case. The predetermined condition in the reference case is that a temperature of the hydrogen tank is 85° C. and a state of charge (SOC) of the hydrogen tank is 95% at a time of hydrogen fueling completion. The average density of the fueling line is calculated based on: a function of the fuel supply pressure and the supply fuel temperature; and a function of the pressure of the hydrogen tank and the supply fuel temperature. The pressure loss coefficient (K_FL_RTR) of the virtual fueling line is calculated based on a following equation 1 when the first pressure loss coefficient (K_FL_Ref) is greater than the third pressure loss coefficient (K_FL_HRS):

$$K\_FL \_RTR = K\_FL \_HRS \times ( \begin{matrix}K\_FL \_Ref & K\_FL \_H2F )\end{matrix} . \qquad [ Equation 1 ]$$

The pressure loss coefficient (K_FL_RTR) of the virtual fueling line is a equal to the third pressure loss coefficient (K_FL_HRS) when the first pressure loss coefficient (K_FL_Ref) is less than or equal to the third pressure loss coefficient.

The inner diameter (d_FL) of the virtual fueling line is calculated based on a following equation 2:

$$d\_FL \_RTR = d\_FL \_Ref * {( K\_FL \_Ref / K\_FL \_RTR )}^{0.25} \qquad [ Equation 2 ]$$

wherein d_FL_Ref is the inner diameter of the reference charging line, K_FL_RTR is the pressure loss coefficient of the virtual fueling line, and K_FL_Ref is the first reference pressure loss coefficient. The RTR simulator searches for a pressure ramp rate (PRR) that does not exceed a predetermined limit condition based on the calculated pressure loss coefficient of the virtual fueling line.

In accordance with another aspect of the present invention, there is provided an apparatus for performing a hydrogen fueling simulation according to a Real-Time Response Hydrogen fueling Protocol (RTR-HFP) including a communication module configured to obtain information on at least one of a capacity of a largest hydrogen tank equipped for hydrogen fueling in a real-case scenario, a total capacity of hydrogen tanks, a supply fuel temperature of a fueling line, a supply fuel pressure, and a pressure of a hydrogen tank; and an RTR simulator operably coupled to the communication module and configured to: extract, from a predefined lookup table, a first pressure loss coefficient corresponding to a fueling line pressure loss coefficient that satisfies a predetermined condition in a reference case and a second pressure loss coefficient corresponding to a pressure loss coefficient for SAE test configuration in H2Fills, based on the obtained information; calculate an average density in the fueling line; calculate a third pressure loss coefficient based on the average density, a measured mass flow rate, and a pressure difference between a fuel supply pressure and a hydrogen tank pressure in the fueling line; and calculate a pressure loss coefficient of a virtual fueling line based on the first pressure loss coefficient, second pressure loss coefficient, and the third pressure loss coefficient. The RTR simulator extracts, from the predefined lookup table, an inner diameter of a reference fueling line that satisfies a predetermined condition in the reference case, and calculates an inner diameter of the virtual fueling line based on the calculated pressure loss coefficient of the virtual fueling line, the extracted first pressure loss coefficient, and the extracted inner diameter of the reference fueling line. The RTR simulator searches for a pressure ramp rate (PRR) that does not exceed a predetermined limit condition based on the calculated pressure loss coefficient of the virtual fueling line. The apparatus further comprises a controller operably coupled to the communication module and the RTR simulator, and configured to provide information on candidate PRRS for searching the PRR to the RTR simulator.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a diagram illustrating a real-time communication-based hydrogen fueling system according to one embodiment of the present invention.

FIG. 2 is a block diagram illustrating the internal configuration included in the system of FIG. 1.

FIG. 3 is an exemplary diagram illustrating the RTR-HFP operating concepts according to the present invention.

FIG. 4 is an exemplary diagram illustrating assumptions applied to the RTR simulator (RTR-Simulator) included in the RTR-HFP apparatus according to the present invention.

FIG. 5 is an exemplary diagram illustrating the RTR-HFP development and application process according to the present invention.

FIG. 6 is a diagram illustrating a procedure for calculating K_FL_HRS.

FIG. 7 is a diagram illustrating a predefined lookup table used by the RTR-HFP apparatus according to the present invention.

FIG. 8 is a diagram illustrating a method for interpolating lookup table values in the RTR-HFP according to the present invention.

FIG. 9 is a diagram illustrating a procedure for calculating the K_FL_RTR value in an RTR-HFP according to the present invention.

FIG. 10 is a diagram illustrating a procedure for searching for an optimal PRR in an RTR-HFP apparatus according to the present invention.

FIG. 11 is a block diagram illustrating the configuration of an RTR-HFP apparatus according to the present invention.

### DETAILED DESCRIPTION OF THE INVENTION

The present invention includes various modifications and embodiments. Therefore, specific embodiments are illustrated and described in detail in the drawings. However, this is not intended to limit the present invention to specific embodiments, but rather to encompass all modifications, equivalents, and alternatives falling within the scope of the present invention.

When a component is referred to as being “connected” or “coupled” to another component, it should be understood that it may be directly connected or connected to that other component, but there may also be other components present in between. Conversely, when a component is referred to as being “directly connected” or “directly coupled” to another component, it should be understood that there are no other components present in between.

Terms such as “first” and “second” may be used to describe various components, but these components should not be limited by these terms. These terms are used to distinguish one component from another.

The terminology used herein is used to describe specific embodiments and is not intended to limit the present invention. Singular expressions include plural expressions unless the context clearly dictates otherwise. In this specification, terms such as “comprise”, “include”, or “have” indicate the presence of a feature, number, step, operation, component, part, or combination thereof described in the specification, but should be understood as not excluding the possibility of the presence or addition of one or more other features, numbers, steps, operations, components, parts, or combinations thereof.

Furthermore, terms such as “part,” “portion,” “module,” and “controller” described in the specification refer to a unit that processes at least one function or operation, which may be implemented using hardware, software, or a combination of hardware and software.

In some cases, to avoid ambiguity in the concepts of the present invention, well-known structures and devices may be omitted or illustrated in block diagram form focusing on the core functions of each structure and device.

Furthermore, the same reference numerals are used throughout this specification to describe the same components. In addition, it is to be understood that the components of the embodiments described with reference to each drawing are not limited to the specific embodiments, but may be implemented to be included in other embodiments within the scope in which the technical idea of the present invention is maintained, and that multiple embodiments may be re-implemented as a single integrated embodiment even if a separate description is omitted.

The present invention proposes a new HPF that dramatically improves the limitations as well as the low efficiency problem in the application scope and method of the existing HFP. In view of the fact that the problems of the conventional HFP originated from a premise of non-communication, the new HFP was designed to be dedicated to communication. In addition, two thermodynamic models are designed to develop the new HFP. One is a thermodynamic model (e.g., Simple Thermodynamic Model, STM) that acts as a control engine for the fueling process, and the other is the Rigorous thermodynamic model (RTM) that acts as a testbed for the new HFP. The new HFP proposed in the present invention is defined as the Real Time Responding-Hydrogen Fueling Protocol (RTR-HFP).

Hereinafter, the present invention will be described in detail with reference to the attached drawings.

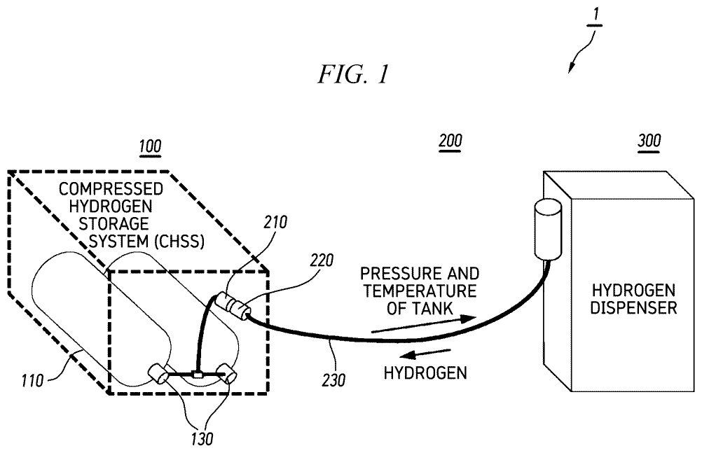

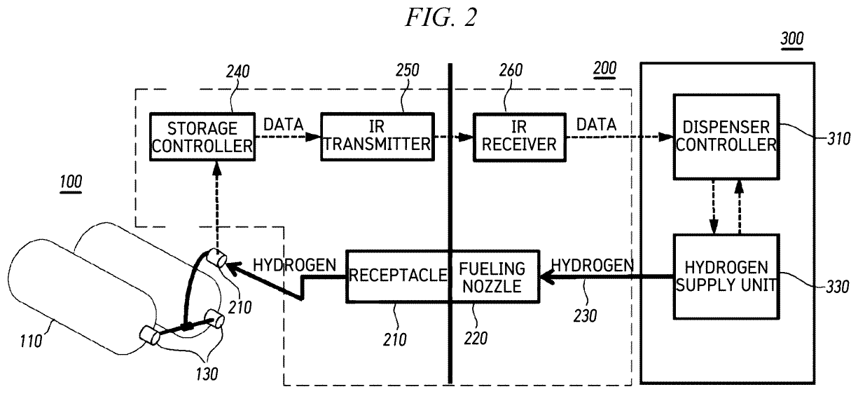

FIG. 1 is a diagram illustrating a real-time communication-based hydrogen fueling system according to one embodiment of the present invention, and FIG. 2 is a block diagram illustrating the internal configuration included in the system of FIG. 1.

Referring to FIG. 1, the real-time response hydrogen fueling system (1) may include at least one Compressed Hydrogen Storage System (CHSS) 100, a hydrogen transfer device 200, and a hydrogen dispenser 300. However, the hydrogen charging system (1) of FIG. 1 is merely one embodiment of the present invention, and thus the present invention is not limited to FIG. 1. The CHSS 100 may be installed in a vehicle, etc.

At this time, each component of FIG. 1 may generally be connected through a network. For example, as illustrated in FIG. 1, at least one CHSS 100 can be connected to a hydrogen transport device 200 through a network. In addition, the hydrogen transport device 200 can be connected to at least one CHSS 100 and a hydrogen dispenser 300 through a network. In addition, the hydrogen dispenser 300 can be connected to the hydrogen transport device 200 through a network. Here, the network refers to a connection structure that enables information exchange between each node, such as a plurality of terminals and servers, and examples of such a network include, but are not limited to, a local area network (LAN), a wide area network (WAN), the Internet (World Wide Web, WWW), a wired and wireless data communication network, a telephone network, a wired and wireless television communication network, a cellular communication network, etc.

Hereinafter, each component of the hydrogen fueling system 1 will be described with reference to FIGS. 1 and 2. A compressed hydrogen storage system (CHSS) 100 may include a hydrogen tank 110 and a hydrogen tank valve 130. In FIGS. 1 and 2, two hydrogen tanks are illustrated as an example, but more than one hydrogen tank may be provided. The CHSS 100 may be installed in a vehicle or transportation means and is provided to receive and store hydrogen as fuel. Furthermore, the hydrogen tank valve 130 includes a pressure sensor and a temperature sensor, and thus can measure the pressure and temperature of hydrogen within the hydrogen tank 110 and transmit the measured values to the storage controller 240 of the hydrogen transport device 200.

The hydrogen transfer device 200 may include a receptacle 210 that transfers hydrogen injected from a hydrogen supply unit (or hydrogen supply module) 330 to a hydrogen tank valve 130, a wireless communication module provided for wireless communication between a hydrogen supply hose 230 and a dispenser controller 310 in a hydrogen dispenser 300, and a storage controller 240 that converts detection data into data for wireless communication and outputs the data. The hydrogen transfer device 200 may further include the fueling nozzle 220 that is connected between the receptacle 210 and the hydrogen supply module 330 and supplies hydrogen to a hydrogen tank 110 via the hydrogen tank valve 130. At this time, the wireless communication module may include a transmitter (e.g., an IR transmitter) 250 installed on the other side of the storage controller 240 installed on one side of the receptacle 210 where hydrogen is injected into the vehicle, and a receiver (e.g., an IR receiver) 260 connected to the IR transmitter 250 on one side and connected to the dispenser controller 310 on the other side.

The hydrogen dispenser 300 may include the dispenser controller 310 that receives sensing data including pressure and temperature within the hydrogen tank 110, and a hydrogen supply module 330 that supplies hydrogen within the hydrogen tank 110 based on the sensing data. The dispenser controller 310 may receive data from the wireless communication module and the hydrogen supply module 330, calculate a real-time pressure ramp rate within the hydrogen supply module 330, and return the calculated pressure ramp rate (average pressure ramp rate) to the hydrogen supply module 330.

Referring to FIGS. 1 and 2, it can be seen that the CHSS 100 is supplied with hydrogen from the hydrogen dispenser 300 according to real-time response hydrogen fueling control. For real-time response hydrogen fueling control, a transmitter (not shown) of the CHSS 100 is provided to transmit information to the hydrogen transfer device 200 and/or the hydrogen dispenser 300 by means of wireless communication, etc. The transmitter (not shown) of the CHSS 100 is provided to transmit information to the hydrogen transfer device 200 and/or the hydrogen dispenser 300 by means of wireless communication, etc.

The transmitter of the CHSS 100 can initially transmit information on the temperature of the hydrogen tank 110, the pressure of the hydrogen tank 110, and the state of charge (SOC) to the hydrogen transfer device 200 using wireless communication, etc. The hydrogen tank valve 130 may be configured to measure the temperature and pressure of the hydrogen tank 110. Furthermore, the transmitter of the CHSS 100 may transmit information on the number and volume of hydrogen tanks 110 to the hydrogen transfer device 200 via wireless communication, etc., and thereby transmit the information to the hydrogen dispenser 300.

The following description of the RTR-HFP according to the present invention, unless specifically mentioned, may be based on the contents of Korean Patent No. 10-2021-0152613, a prior application of this patent. Furthermore, the RTR-HFP according to the present invention complies with the provisions of ISO standard ISO 19885-3 (Annex I).

The English abbreviations used in connection with the technology according to the present invention are summarized in Tables 1 to 4 below and will not be described again herein.

TABLE 1

| Symbol | meaning |
|---|---|
| _b | Value of before time step |
| _C | Temperature in degrees Celsius, ° C. |
| _Comm | Communicated value |
| _Mea | Measured value |
| A_In | Liner internal surface area, m² |
| Alpha_a | Heat transfer coefficients of air-contacted |
| | surface, kW/K |
| Alpha_g | Heat transfer coefficients of hydrogen gas- |
| | contacted surface, kW/K |
| C_Comp | Heat capacity of composite, kW/K |
| C_Lin | Heat capacity of liner, kW/K |
| Calc_Intv | Repetition time, s |
| Cp_Comp | Specific heat capacity of composite, kJ/kgK |
| Cp_Lin | Specific heat capacity of liner, kJ/kgK |
| Cv_Tk_b | Specific heat capacity at constant volume, |
| | kJ/kgK |
| d_FL | Internal diameter at breakaway inlet, m |
| d_FL_Ref | Internal diameter at breakaway inlet |
| | reference, m |
| d_In_Tk | Internal diameter of tank, m, |
| delta_P | Differential pressure, MPa |
| delta_P_Ref | Reference differential pressure, MPa |
| dt_CPU | Time step of t_CPU, s |
| dt_RTR | Time step of t_RTR, s |
| dt_RTR | Time interval in RTR-HFP, s |
| FC | Fuelling Command |

TABLE 2

| Symbol | meaning |
|---|---|
| FM | Mass flow rate limit, kg/s |
| Fun_{—} | User-defined functions |
| Gap_FM | Difference from upper mass flow limit, kg/s |
| Gap_T_Tk_Lim | Difference from upper temperature limit, ° C. |
| h_TkInlet | Enthalpy into tank, kJ/kg |
| k_Comp | Thermal conductivity of composite, kW/mK |
| K_FL | Coefficient of pressure loss, m⁻⁴ |
| K_FL_H2F | K_FL extracted for “SAE Test Configuration” |
| | in H2FillS, m⁻⁴ |
| K_FL_HRS | K_FL calculated from data received from “Real |
| | HRS”, m⁻⁴ |
| K_FL_Ref | K_FL extracted for “SAE Test Configuration” |
| | in RTR-Simulator, m⁻⁴ |
| K_FL_RTR | K_FL extracted for “Real HRS” in RTR- |
| | Simulator, m⁻⁴ |
| k_Lin | Thermal conductivity of liner, kW/mK |
| lrho_Ba | Density of hydrogens at breakaway, kg/m³ |
| M_Comp | Mass of CFRP, kg |
| m_FL | Mass flow rate, kg/s |
| m_FL_Max | Maximum mass flow rate, kg/s |
| m_FL_Sum | Total mass flow, kg |
| m_Lin | Mass of liner, kg |
| P_Ba | Supply gas pressure, MPa |
| P_Ba_0 | Initial supply gas pressure, MPa |
| P_Ba_Lim | Supply gas pressure limit, MPa |
| P_Ba_Ref | Reference supply gas pressure, MPa |
| P_Class | Protocol's nominal working |
| | pressure (35, 50 or 70), MPa |
| P_Tk | Pressure inside tank, MPa |

TABLE 3

| Symbol | meaning |
|---|---|
| P_Tk_0 | Pressure inside tank at t = 0, MPa |
| P_Tk_b | Pressure inside tank at previous timestep, |
| | MPa |
| P_Tk_Lim | Pressure limit inside tank, MPa |
| P_Tk_Ref | Reference pressure inside tank, MPa |
| PRR | Average Pressure Ramp Rate, MPa/min |
| PRR_D_Lim | PRR reduction limit, MPa/min |
| PRR_La | Large PRR, MPa/min |
| PRR_Lim | Limitation of Average Pressure Ramp Rate, |
| | MPa/min |
| PRR_Max | Maximum PRR, MPa/min |
| PRR_Mi | Middle PRR, MPa/min |
| PRR_New | New Average Pressure Ramp Rate, MPa/mi |
| PRR_Sm | Small PRR, MPa/min |
| PRR_U_Lim | PRR Increase limit, MPa/min |
| PRRs | Average Pressure Ramp Rate, MPa/s |
| Q_In_a | Heat transfer at air-contacted surface, kJ/s |
| Q_In_g | Heat transfer at hydrogen gas-contacted |
| | surface, kJ/s |
| Q_Tk | Heat transfer through tank walls, kJ/s |
| rho_Comp | Density of composite, kg/m³ |
| rho_FL | Density of hydrogen in fuelling line, kg/m³ |
| rho_FL_Av | Average density in fuelling line, kg/m³ |
| rho_H2_Basic | Hydrogen gas density limit corresponding to |
| | P_Class, kg/m3 |
| rho_H2_Class | Hydrogen gas density corresponding to |
| | P_Class, kg/m³ |
| rho_Lin | Density of liner, kg/m³ |
| rho_Tk | Density at breakaway, kg/m³ |

TABLE 4

| Symbol | meaning |
|---|---|
| rpt_Tot | Number of iterations |
| SOC | State Of Charge, % |
| SOC_G | Target SOC, % |
| T_Amb | Ambient air temperature, K |
| T_AmbC | Ambient air temperature, ° C. |
| T_Ba | Hydrogen temperature from brakeaway, K |
| T_Ba_Ref | Reference hydrogen temperature from |
| | brakeaway, K |
| t_CPU | Time of CPU with RTR-HFP, s |
| t_final_Min | Minimum ending time, s |
| t_Real | Real time, s |
| t_RTR | Time in RTR-HFP, s |
| T_Tk | Temperature in tank, K |
| T_Tk_b | Previous gas temperature in tank, K |
| T_Tk_Lim | Limit of temperature in tank for |
| | Calculation of PRR, K |
| T_Tk_Max | Maximum temperature of tank, K |
| T_Tk_Soak | Soak temperature of tank, K |
| Thick_Comp | Wall Thickness of composite, m |
| Thick_Lin | Wall Thickness of liner, m |
| TV | Total volume of the VFS, m³ |
| TVL | The largest tank volume of any of individual tank |
| | in the VFS, m³ |
| V_Tk | Volume of the tank, m³ |
| v_TkInlet | Velocity of flowing hydrogen, m/s |

The key difference between the conventional Hydrogen Fueling Protocol (HFP) and the Real-Time Responding-Hydrogen Fueling Protocol (RTR-HFP) of the present invention is that the conventional hydrogen fueling protocol performs hydrogen fueling simulation during the design phase of the hydrogen fueling protocol, whereas the real-time responsive hydrogen fueling protocol of the present invention performs hydrogen fueling simulation during the use phase of the hydrogen fueling protocol. Conventional HFPs perform simulations during the design phase, requiring numerous assumptions and constraints. However, the RTR-HFP of the present invention performs simulations in real time during the use phase, significantly reducing the need for these assumptions and constraints.

Furthermore, because the RTR-HFP according to the present invention performs real-time simulations during the use phase of the hydrogen fueling protocol, it improves application flexibility, significantly overcoming limitations in scope and method of application. While initially developed for 70 MPa, RTR-HFP is applicable to all pressure classes, and future upgrades will ensure broader compatibility across various fueling configurations.

Protocols that apply a single Average Pressure Ramp Rate (APRR) from the beginning to the end of hydrogen fueling make it impossible to adapt a high APRR due to bottlenecks that occur in the early stages of hydrogen fueling. Furthermore, when calculating APRR using lookup tables generated through simulation during the development phase, it is difficult to freely increase the number of lookup tables. However, in the case of RTR-HFP, the hydrogen refueling protocol derives the Pressure Ramp Rate (PRR) using real-time simulation during the application phase. This allows for higher PRR values to be applied in the later stages of hydrogen fueling.

Furthermore, RTR-HFP according to the present invention reflects the higher temperature inside the hydrogen tank 110 when deriving the PRR, thereby reducing fueling supply time under specific conditions. Below, the criteria and requirements applied to the RTR-HFP of the ISO 19885-3:2024 standard according to the present invention are briefly described.

Starting the Refueling (fuel supply) Process: Before starting the refueling process, the following items must be checked: a) communication state, b) pressure sensor integrity, c) TV, TVL, ambient temperature, and CHSS tank pressure. If all results are within process limits and are normal, the refueling process begins.

Protocol-specific communication: a) RTR-HFP uses static data (TV and TVL) and dynamic data (pressure and temperature of the CHSS tank gas) within the protocol for PRR calculation (related to dynamic control of fuel supply and safety functions). Therefore, it is classified as UCDC Level 3 according to Section 3.25 of ISO 19885-1. Therefore, the communication requirements for RTR-HFP follow ISO 19885-2. b) If communication is interrupted for more than 5 seconds while refueling using the communication method specified in ISO 19885-2, the system may continue refueling by switching to the non-communication refueling method of the MCF-HF-G refueling protocol from the next time interval. c) Notwithstanding the criteria in a), IR communication may be used under the supervision of a qualified process engineer for temporary refueling of CHSS with hydrogen under controlled conditions for R&D or other purposes.

General Requirements for IR Communication: The general requirements for IR communication in RTR-HFP (except for specific provisions noted below) follow the requirements for the communication-based refueling method of the MCF-HF-G refueling protocol.

### Specific Requirements for Measured Pressure:

a) Range: 000.0 to 100.0
b) The vehicle shall transmit the measured CHSS gas pressure in MPa. The hydrogen dispenser 300 must monitor the measured pressure and terminate fuel delivery as quickly as possible, but within 5 seconds, if the measured pressure exceeds the Maximum Operating Pressure (MOP) defined in ISO 19885-1:2024, Section 3.15.

### Specific Requirements for Measured Temperature

a) Range: 16.0 to 425.0
b) The vehicle must transmit the CHSS measured gas temperature in Kelvin. The measured temperature must represent the bulk average CHSS gas temperature. The hydrogen dispenser 300 must monitor the measured temperature. If the measured temperature exceeds the specified maximum operating vehicle CHSS gas temperature, fuel delivery must be terminated as quickly as possible, but within 5 seconds. A specific requirement for optional data is the TVL data requirement. The vehicle must transmit the largest hydrogen tank capacity, known as TVL, in the optional data field. TVL is the size of the largest tank capacity in the CHSS 100.

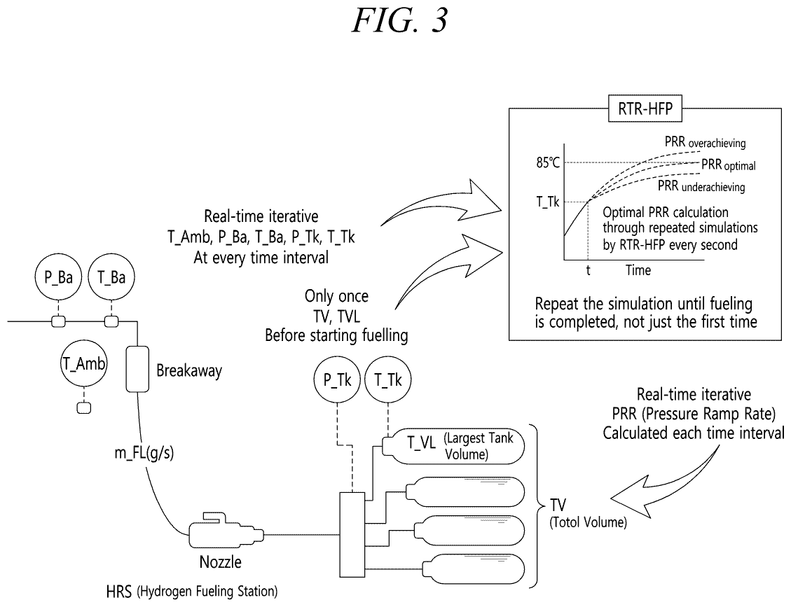

FIG. 3 is an exemplary diagram illustrating the RTR-HFP operating concepts according to the present invention.

Referring to FIG. 3, the RTR-HFP apparatus of the present invention is an apparatus (device) for simulating hydrogen fueling by executing a real-time response hydrogen fueling (hydrogen supply) protocol (RTR-HFP). The RTR-HFP apparatus receives data from a vehicle and a hydrogen dispenser 300 at each time interval and may calculate a pressure ramp rate (or average pressure ramp rate) (PRR) based on the data. The RTR-HFP apparatus then transmits the calculated PRR to the hydrogen dispenser 300 to supply fuel according to the calculated PRR, thereby becoming a real-time response hydrogen fueling protocol. As illustrated in FIG. 3, the RTR-HFP apparatus may obtain data by receiving ambient air temperature (T_Amb), fuel supply (gas) pressure (P_Ba), and fuel supply temperature (fuel temperature from breakaway) (T_Ba) from the hydrogen dispenser 300, as well as the pressure (P_Tk) and temperature (T_Tk) within the hydrogen tank from the vehicle. This data is transmitted to the RTR simulator (also known as the RTR-Simulator, simulator, etc., but hereinafter referred to as the RTR simulator) built into the RTR-HFP apparatus.

The RTR simulator may execute, based on this data, a fuel supply simulation from the time the data is received until the hydrogen fuel supply process is completed (until the SOC reaches a target value (e.g., 95 percent (95%)), thereby calculate the maximum temperature (T_Tk_Max) of the hydrogen tank 110 within the vehicle. If T_Tk_Max is lower than 85° C., the RTR simulator may repeat the simulation with a higher PRR. If T_Tk_Max is higher than 85° C., the RTR simulator repeats the simulation with a lower PRR. This iterative process of the RTR simulator continues in real time until a PRR is found where T_Tk_Max is exactly 85° C. The RTR-HTP apparatus then transmits information about the PRR at which T_Tk_Max reaches 85° C. to the hydrogen dispenser 300, which can then apply this information to proceed with the hydrogen fueling process for the next time interval.

The RTR simulator may calculate the PRR once and applying it throughout the hydrogen fueling process. However, the RTR simulator recalculates and applies the PRR at each time interval. This is for two reasons. First, as the hydrogen fueling process progresses, a higher PRR can be applied than at the start, helping to reduce the overall hydrogen fueling time. Second, the PRR can be recalculated based on the temperature of the vehicle's hydrogen tank 110 measured at each time interval, ensuring that the hydrogen tank 110 temperature does not exceed 85° C., thereby maintaining optimal control during the hydrogen fueling process.

Assumptions applied to the RTR-HFP according to the present invention

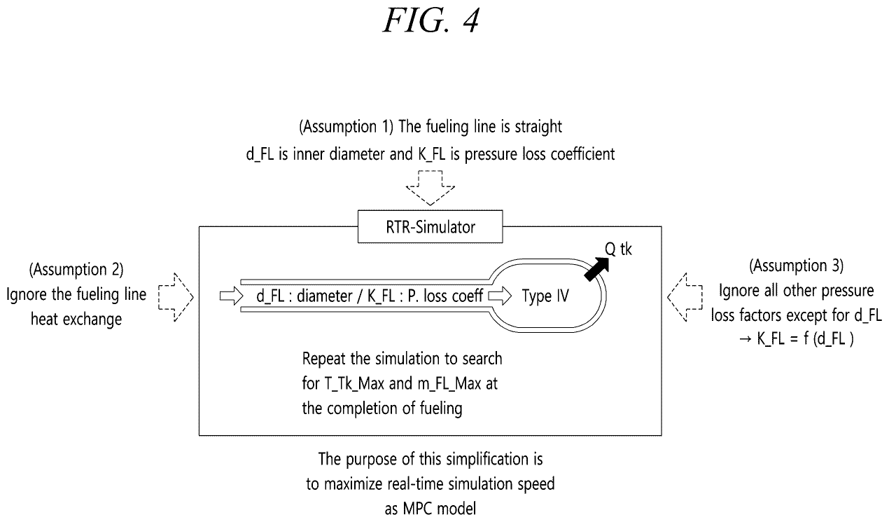

FIG. 4 is an exemplary diagram illustrating assumptions applied to the RTR simulator (RTR-Simulator) included in the RTR-HFP apparatus according to the present invention.

The RTR simulator in the RTR-HFP apparatus may determine the optimal PRR to be applied to the next time interval through fuel simulations performed at each time interval. The optimal PRR is defined as the PRR that achieves the target SOC in the shortest possible time while ensuring that the gas temperature inside the hydrogen tank 110 does not exceed 85° C. The RTR simulator typically executes approximately five simulations in a single iteration to find the optimal PRR. If the time step is 1 second, approximately five simulations must be completed within that time interval. To increase simulation speed, the RTR simulator is designed based on several assumptions. For reference, the time period represents the duration of a single simulation run, while the time period refers to the period during which the PRR is recalculated. For example, the time step of the RTR simulator is 1 second, while time interval ranges for recalculation PRR in RTR-HFP is from 1 to 20 seconds.

As illustrated in FIG. 4, the RTR simulator operates under three assumptions. The first assumption (Assumption 1) is that the fueling line is regarded as a straight pipe, the inner diameter is defined as d_FL, and the pressure loss coefficient is defined as K_FL. The second assumption (Assumption 2) is that heat transfer through the fueling line wall is ignored. Assume no heat transfer through the fueling line walls. The third assumption (Assumption 3) is that the only factor affecting the pressure loss coefficient is d_FL. These three assumptions allow for the connection between the reference case and the real case, facilitating the calculation of the mass flow rate (m_FL) of the fueling line and the temperature (T_Tk) inside the hydrogen tank 110.

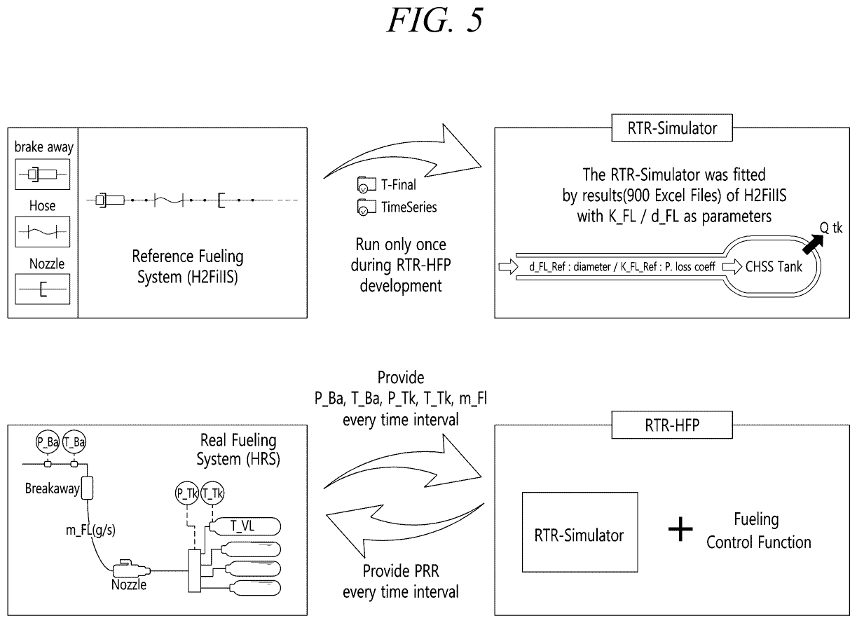

FIG. 5 is an exemplary diagram illustrating the RTR-HFP development and application process according to the present invention.

As described above, RTR-HFP can improve simulation speed by applying the three assumptions. However, applying these assumptions to improve simulation speed may reduce the accuracy of the RTR simulator. Fitting for the RTR simulator can be performed using H2Fills, developed and publicly available by NREL. H2Fills is a hydrogen fueling process simulator that served as the basis for the development of SAE J2601-5. As shown in FIG. 5, fitting for the RTR simulator is performed once during the RTR-HFP development phase. However, if performance improvements are required for RTR-HFP, this fitting process must be re-performed.

### Overview of the RTR-HFP Operation Process

In the RTR-HFP according to the present invention, a new optimal PRR is periodically recalculated and applied to the hydrogen fueling process. The optimal PRR is defined as the PRR that minimizes the hydrogen fueling time while ensuring that the maximum temperature (T_Tk_Max) of the hydrogen tank 110 and the maximum mass flow rate (m_FL_Max) of the fueling line do not exceed the limits when the target SOC is reached. The RTR simulator may utilize static data (e.g., the volume of the largest hydrogen tank (TVL) and the total volume (TV) of all hydrogen tanks) and dynamic data (e.g., hydrogen tank pressure, hydrogen tank temperature, and mass flow rate) obtained from the hydrogen dispenser 300 and the vehicle. The RTR simulator searches for the optimal PRR through iterative simulations.

As described above, to increase simulation speed, the RTR simulator assumes the hydrogen fueling line as a straight pipe, and the pressure loss coefficient and inner diameter are defined as K_FL and d_FL, respectively. To increase the accuracy of the simulation for a physical model (a real hydrogen refueling station (HRS)), the Simple Model according to the present invention is fitted using a rigorous model (H2FillS). The fitting parameters are the pressure loss coefficient (K_FL) of the fueling line and the inner diameter (d_FL) of the fueling line.

Table 5 below shows the types and uses of hydrogen refueling models related to the present invention.

TABLE 5

| Type | Entity | Role |
|---|---|---|
| Physical model | HRS | Entity for fuelling |
| | | operation |
| Rigorous model | SAE Test | Simple model fitting to |
| | Configuration | produce the same |
| | of H2Fills | simulation results for |
| | | the same TVL |
| Simple model | RTR-Simulator | Calculates PRR through |
| | | HRS simulation |

The RTR-HFP includes a physical model, a rigid model (Rigorous mode), and a simple model used by the RTR simulator according to the present invention, which are interconnected through parameters and equations. Referring to Table 5, the physical model represents the HRS (Hydrogen Refueling Station) as an entity for refueling operations. The rigid model (Rigorous mode) is used to fit the simple model to generate identical simulation results for the same TVL as the H2FillS SAE Test Configuration. The simple model is the model used by the RTR simulator to derive the PRR through the HRS simulation.

Table 6 below shows the types and uses of the four K_FLs in the RTR-HFP.

TABLE 6

| Applicable | | |
|---|---|---|
| Model | Symbol | Usage and Meaning |
| Physical model | K_FL_HRS | Real HRS pressure loss |
| | | coefficient |
| Rigorous model | K_FL_H2F | Rigorous model pressure loss |
| | | coefficient |
| Simple model | K_FL_Ref | Pressure loss |
| | | coefficient (used in the |
| | | Simple model) calibrated to |
| | | simulate the rigorous model |
| | K_FL_RTR | Pressure loss |
| | | coefficient (used in the |
| | | Simple model) calibrated to |
| | | simulate the physical model |

Referring to Table 6, RTR-HFP uses four types of pressure loss coefficients (K_FL). K_FL_HRS represents the pressure loss coefficient of a real hydrogen refueling station (HRS) fueling line (fuel supply line), and the applied model is a physical model. K_FL_H2F represents the pressure loss coefficient of the Rigorous model. K_FL_Ref and K_FL_RTR are both values applied to the simple mode according to the present invention. K_FL_Ref is a calibrated pressure loss coefficient (the pressure loss coefficient used in simple mode) for simulating the Rigorous model, and K_FL_RTR is a calibrated pressure loss coefficient (the pressure loss coefficient used in simple mode) for simulating the physical model.

The relationships among these four types of pressure loss coefficients (K_FL) are explained below. RTR-HFP utilizes an engineering technique called Model Prediction Control (MPC). MPC is an advanced control method used in control systems that predicts future behavior based on the current state and determines optimal control inputs. Key concepts of MPC include the use of predictive models, prediction of future behavior, optimization of control inputs, and the utilization of feedback. First, MPC uses a mathematical model representing the dynamic characteristics of a hydrogen refueling system to predict future hydrogen refueling system states based on current states and inputs. Second, it predicts system behavior within a given time range and determines the control inputs required to achieve the control objectives. Third, MPC solves an optimization problem to calculate optimal control inputs based on predicted behavior, taking into account various constraints (e.g., system physical limitations, safety). Fourth, MPC measures the actual system state at each time step and adjusts the predictions and control inputs based on real-time feedback to adapt to changing conditions. MPC has three defining characteristics: constraint handling, multi-objective optimization, and predictive control. By incorporating multiple objectives into the optimization problem, it can simultaneously achieve multiple control objectives. MPC is widely used in complex systems (such as chemical processes and robotics) where achieving optimal performance while managing constraints is crucial.

Referring to FIG. 3, the RTR-HFP apparatus may obtain the capacity of the largest tank (TVL), the total capacity of all tanks (TV), the gas pressure (P_Tk) and the temperature (T_Tk) of the CHSS 100 from a vehicle or other hydrogen-refueling target through a predetermined communication method. In addition, the RTR-HFP apparatus may receive dynamic data such as the ambient air temperature, fuel supply pressure (supply gas pressure (P_Ba)), and supply fuel temperature (hydrogen temperature at break-away (T_Ba)) from the hydrogen dispenser 300.

### Calculating K_FL_HRS

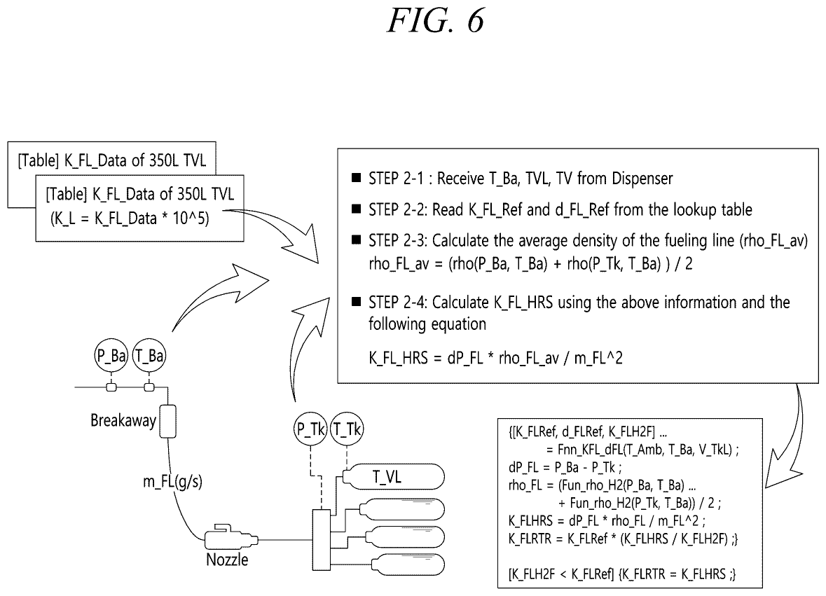

FIG. 6 is a diagram illustrating a procedure for calculating K_FL_HRS.

K_FL_HRS represents the pressure loss coefficient of the fueling line (fuel supply line) in a real-case hydrogen refueling station (HRS). Here, K_FL_HRS is used to calculate K_FL_RTR, which can be defined as a pressure loss coefficient corrected for simulating a physical model (the pressure loss coefficient used in simple mode) or a pressure loss coefficient in a virtual fueling line.

Referring to FIG. 6, the RTR-HFP apparatus may recalculate K_FL_HRS based on data transmitted from the vehicle (or hydrogen fueling target) and the hydrogen dispenser 300. If the data is accurately measured, the pressure loss coefficient (K_FL_HRS) value will also be accurately calculated. Here, the method by which the RTR-HFP apparatus calculates the pressure loss coefficient (K_FL_HRS) is specifically described.

To calculate the pressure loss coefficient (K_FL_HRS), the RTR-HFP apparatus may receive the TVL, TV, hydrogen tank pressure (P_Tk), and temperature (T_Tk) from a vehicle or other device via a predetermined communication, and can also receive the TVL, TV, T_Ba, ambient air temperature (T_Amb), and P_Ba from a hydrogen dispenser 300 (Step 2-1). The RTR-HFP apparatus can read or extract the pressure loss coefficient (K_FL_Ref) of a fueling line that satisfies at lease one predetermined condition in a reference case and the inner diameter (d_FL_Ref) of the fueling line in the reference case from a predefined lookup table (Step 2-2). In the above reference case, the predetermined conditions may be that the temperature of the hydrogen tank is 85° C. and the state of charge (SOC) of the hydrogen tank is 95% at the time of hydrogen fueling completion.

The RTR-HFP apparatus may calculate the pressure loss coefficient (K_FL_HRS) of the HRS fueling line based on data received from the vehicle 100 and the hydrogen dispenser 300. The pressure loss coefficient (K_FL_HRS) can be calculated using the pressure loss, average density, and mass flow rate of the fueling line in a real case. The average density (ρ(rho)_FL_av)) of the fueling line required to calculate the pressure loss coefficient (K_FL_HRS) is as shown in the following mathematical equation 1 (Equation 1). The average density of the fueling line may be referred to in various ways, such as the average hydrogen density of the fueling line.

$$rho\_FL \_av = ( rho ( P\_Ba , T\_Ba ) + rho ( P\_Tk , T\_Ba ) ) / 2 \qquad [ Equation 1 ]$$

As shown in Equation 1 above, the average density of the fueling line can be calculated based on the density functions for the fuel supply pressure and temperature, P_Ba and T_Ba, and the density functions for the pressure inside the hydrogen tank, P_Tk, and the fuel supply temperature (T_Ba). Furthermore, since it is assumed that there is no heat loss or exchange in the fueling line, T_Ba and T_Tk are equal, and therefore the known T_Ba value can be used instead of the temperature (T_Tk) of the hydrogen tank.

Thereafter, the RTR-HTP apparatus may calculate the pressure loss coefficient (K_FL_HRS) of the fueling line in a real-case hydrogen refueling station (HRS) based on the information from steps 2-1 to 2-3 illustrated in FIG. 6 and the following Equation 2.

$$K\_FL \_HRS = dP\_FL * rho\_FL \_av / {m\_FL}^{2} \qquad [ Equation 2 ]$$

In the above Equation 2, dp_FL is the pressure difference (Δp) in the fueling line, calculated as P_Ba−P_tk, and corresponds to the difference between the fuel supply pressure and the pressure in the hydrogen tank. m_FL is the mass flow rate in the fueling line, which can be measured by a flow meter installed in a hydrogen refueling station (HRS) in the real case. The average density in the fueling line is derived from pressure and temperature, and the mass flow rate is measured by a flow meter installed in a hydrogen refueling station (HRS) in the real case.

Thus, the RTR-HFP apparatus may calculate the K_FL_HRS value based on the above Equation 2. The average density (ρ(rho) FL_av) in the above Equation 2 is as defined in the Equation 1. The RTR-HFP apparatus may calculate the pressure loss coefficient (K_FL_HRS) based on the average density calculated according to Equation 2, the measured mass flow rate, and the pressure difference (dp_FL) between the fuel supply pressure and the hydrogen tank pressure in the fueling line. In Equation 2, the square value of m_FL is inputted as a factor.

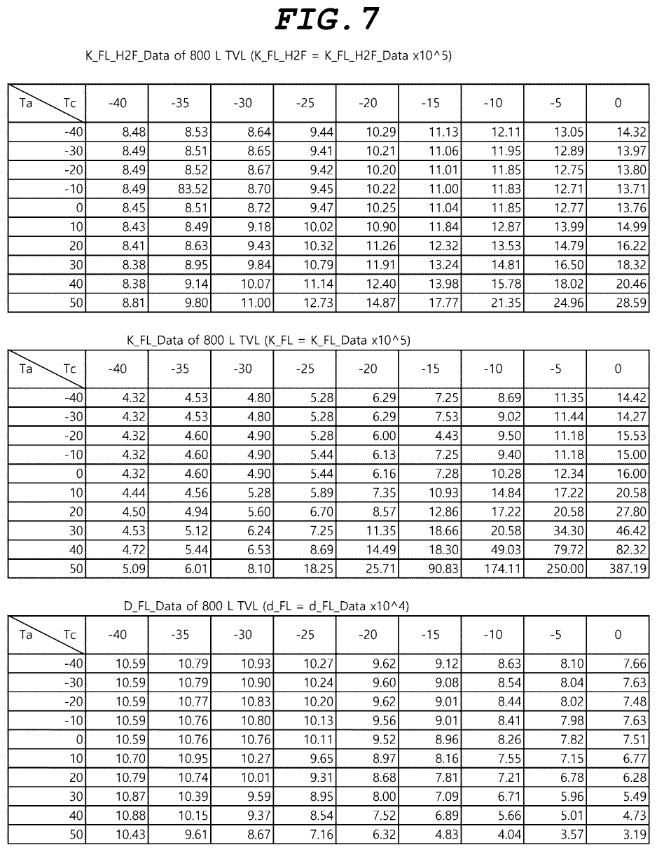

FIG. 7 is a diagram illustrating a predefined lookup table used by the RTR-HFP apparatus according to the present invention.

The RTR-HFP apparatus may obtain K_FL_H2F, K_FL_Ref, and d_FL_Ref from a predefined lookup table. When searching or retrieving values from the lookup table, the obtained TVL, ambient air temperature (T_Amb=Ta), and supply fuel temperature (Tc) are used. The predefined lookup table includes pressure loss coefficient values (K_FL_Ref, K_FL_H2F) and inner diameter (d_FL_Ref) according to the ambient air temperature (T_Amb=Ta) and the supply fuel temperature (Tc) for each TVL value (50 L, 100 L, 200 L, 248.6 L, 350 L, 450 L, 500 L, 600 L, 700 L, 800 L).

A predefined (or preset) lookup table may include a first type lookup table comprising pressure loss coefficients (K_FL_H2F) for SAE test configuration in H2FillS for each TVL (per TVL), a second type lookup table comprising pressure loss coefficients of the fueling line, and a second type lookup table comprising inner diameters (d_FL_Ref) of a reference fueling line that satisfy certain conditions in the reference case. As an example, FIG. 7 illustrates the K_FL_H2F, K_FL_Ref, and d_FL_Ref values for a TVL of 800 L. While it is preferable to create a lookup table for each TVL value, this does not exclude the possibility that information related to the capacity of a hydrogen tank other than the TVL value can be generated as a lookup table.

Three types of lookup tables are used in RTR-HFP. There is a K_FL_H2F derived from the H2FillS simulation for the “SAE test configuration”, and there are derived K_FL_Ref and d_FL_Ref to ensure that the RTR simulator of the RTR-HFP apparatus produces the same results as the H2FillS simulation for the “SAE test configuration”. These values are used as references to calculate K_FL_RTR and are therefore denoted as “Ref”. Ten tables may be predefined or generated based on the TVL values (50 L, 100 L, 200 L, 248.6 L, 350 L, 450 L, 500 L, 600 L, 700 L, 800 L). In the lookup table, the process limits for the ambient and supply fuel temperatures of the RTR-HFP can be set to −40° C. to 50° C. for the ambient temperature and −40° C. to 0° C. for the supply fuel temperature. The initial pressure of the CHSS of the RTR-HFP may be set to 0.5 MPa.

If these TVL values do not match the values listed in the lookup table but are intermediate value(s) between the listed values, the RTR-HFP apparatus may use an interpolation method to calculate K_FL_H2F, K_FL_Ref, and d_FL_Ref and then extract K_FL_H2F, K_FL_Ref, and d_FL_Ref. The interpolation method is briefly described below.

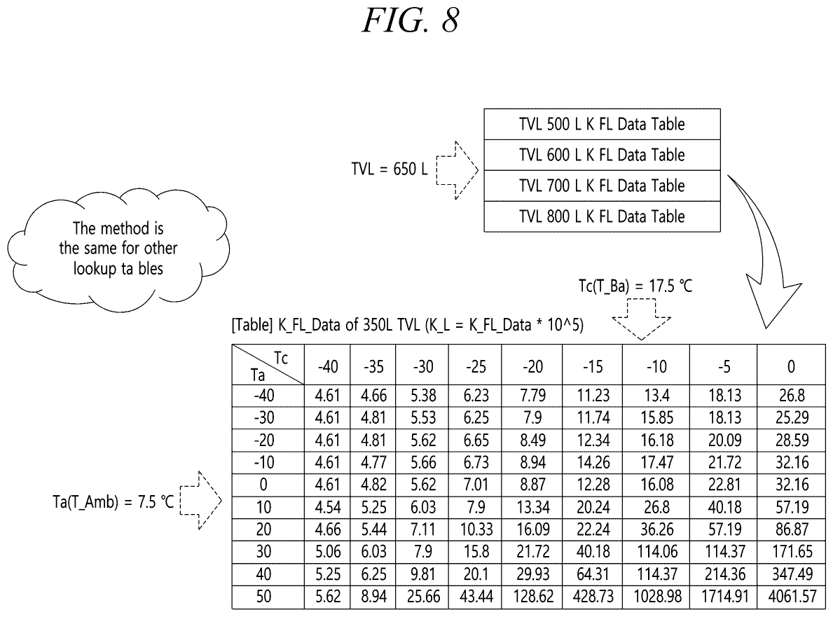

FIG. 8 is a diagram illustrating a method for interpolating lookup table values in the RTR-HFP according to the present invention.

Referring to FIG. 8, each table contains 90 values, corresponding to 10 Ta values (from −40° C. to 50° C. at 10° C. intervals) and 9 Tc values (from −40° C. to 0° C. at 5° C. intervals). However, in practice, the Ta and Tc values rarely exactly match the intervals in the table, making it unlikely that the values in the table can be used directly. Therefore, interpolation is required to find intermediate values between these intervals. FIG. 8 illustrates the interpolation method.

### Calculation of K_FL_RTR Value

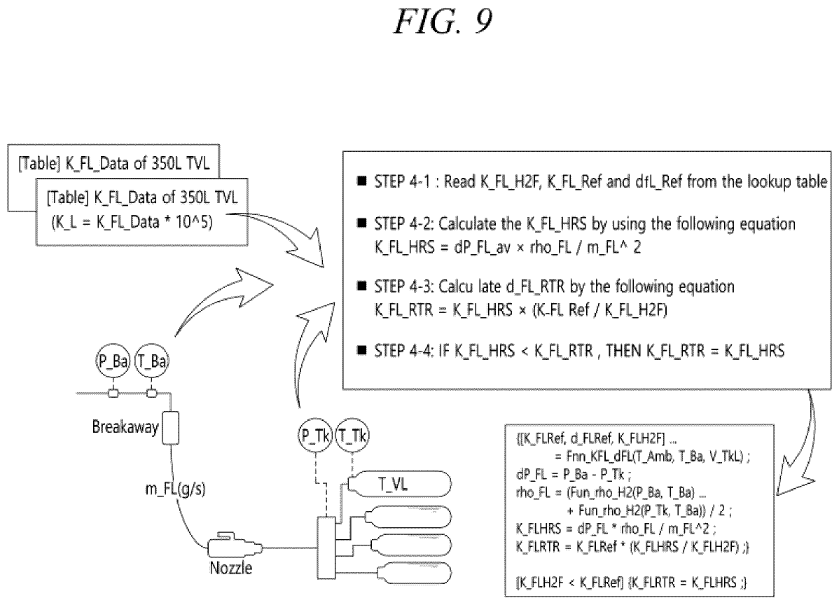

FIG. 9 is a diagram illustrating a procedure for calculating the K_FL_RTR value in an RTR-HFP according to the present invention.

K_FL_RTR represents the pressure loss coefficient of the virtual fueling line in the RTR simulator of the RTR-HFP apparatus, and is used to enable the RTR simulator of the RTR-HFP apparatus to simulate the real (or actual) HRS. This K_FL_RTR is used to calculate the mass flow rate (m_FL) of the fueling line in the RTR simulator of the RTR-HFP apparatus.

Referring to FIG. 9, the RTR-HFP apparatus can read or extract K_FL_H2F, K_FL_Ref, and d_FL_Ref corresponding to the TVL, Ta, and Tc from a predetermined lookup table (Step 4-1). K_FL_HRS can be calculated according to Equation 2 as described above (Step 4-2). The RTR-HFP apparatus may calculate K_FL_RTR using Equation 3 below (Step 4-3).

$$K\_FL \_RTR = K\_FL \_Ref * ( K\_FL \_HRS / K\_FL \_H2F ) \qquad [ Equation 3 ]$$

The RTR-HFP apparatus may calculate K_FL_RTR by multiplying K_FL_HRS by the ratio “K_FL_Ref/K_FL_H2F” according to the Equation 3. If the ratio “K_FL_Ref/K_FL_H2F” is greater than 1 (i.e., K_FL_Ref is greater than K_FL_H2F), the simulation accuracy of the RTR simulator for the real HRS tends to decrease. Therefore, if K_FL_Ref is greater than K_FL_H2F (i.e., K_FL_HRS<K_FL_RTR), the RTR-HFP apparatus may not apply the above Equation 3 to calculate K_FL_RTR, but instead determine K_FL_HRS as the K_FL_RTR value (K_FL_HRS=K_FL_RTR) (Step 4-4).

Calculating d_FL_RTR Value in RTR-HFP

d_FL_RTR represents the inner diameter of the virtual fueling line in the RTR simulator of the RTR-HFP apparatus, and allows the RTR simulator to simulate the real HRS (or actual HRS). The inner diameter (d_FL_RTR) of this virtual fueling line can be used to calculate the temperature (T_Tk) inside the hydrogen tank in the RTR simulator.

Referring to FIG. 9, the RTR-HFP apparatus reads K_FL_Ref and d_FL_Ref from a predefined lookup table (Step 4-1). The RTR-HFP apparatus may calculate the pressure loss coefficient (K_FL_HRS) based on the above Equation 1 and Equation 2 (Step 4-2). The RTR-HFP apparatus may calculate K_FL_RTR using the Equation 3 (Step 4-3). Thereafter, the RTR-HFP apparatus may calculate d_FL_RTR using the following predefined Equation 4.

$$d\_FL \_RTR = d\_FL \_Ref * {( K\_FL \_Ref / K\_FL \_RTR )}^{0.25} \qquad [ Equation 4 ]$$

The RTR-HFP apparatus can simulate the fuel supply process of a physical model (real HRS) using the RTR simulator of simple mode by applying the calculated K_FL_RTR and d_FL_RTR to the RTR simulator. The RTR-HFP apparatus searches for a PRR that does not exceed T_Tk_Max and m_FL_Max. The RTR simulator of the RTR-HFP apparatus may receive candidate PRRs for the next interval from the RTR-HFP algorithm and perform a simulation. Through the simulation, the RTR-HFP apparatus may calculate the maximum gas temperature (T_Tk_Max) inside the CHSS 100 tank and the maximum mass flow rate (m_FL_Max) of the fuel supply line until the target SOC is reached.

The RTR-HFP apparatus may derive an optimal PRR and provide it to the hydrogen dispenser 300. According to the RTR-HFP algorithm, the RTR-HFP apparatus derives an optimal PRR for each interval. The RTR-HFP apparatus then transmits the derived optimal PRR to the hydrogen dispenser 300 for implementation.

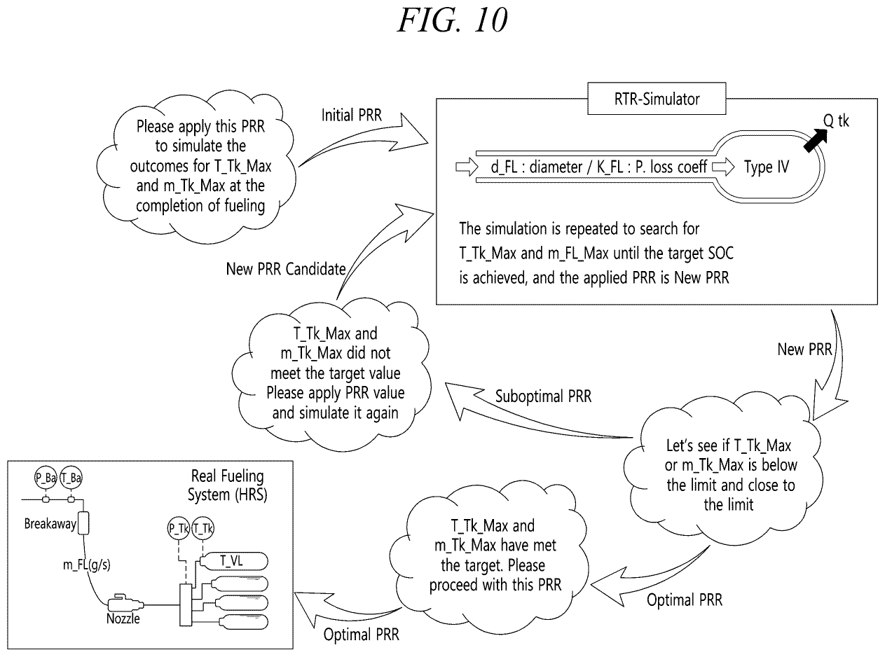

FIG. 10 is a diagram illustrating a procedure for searching for an optimal PRR in an RTR-HFP apparatus according to the present invention.

Referring to FIG. 10, the RTR-HFP apparatus may provide an initial PRR to the RTR simulator to simulate outcomes (results) for the maximum temperature (T_Tk_Max) of the hydrogen tank and the maximum mass flow rate (m_FL_Max) of the fueling line upon completion of fueling. If the maximum temperature (T_Tk_Max) of the hydrogen tank and the maximum mass flow rate (m_FL_Max) of the fueling line do not meet the target value(s), the RTR-HFP apparatus may provide the RTR simulator with a new candidate PRR for the RTR simulator to re-simulate. The RTR-HFP apparatus may repeat the simulation to search for the maximum temperature (T_Tk_Max) of the hydrogen tank and the maximum mass flow rate (m_FL_Max) of the fueling line until the target SOC is achieved, and determine the applied PRR as the new PRR. If the maximum temperature of the hydrogen tank (T_Tk_Max) and the maximum mass flow rate of the fueling line (m_FL_Max) meet the target value(s), this PPR becomes the optimal PRR. The optimal PRR is then applied in the HRS.

As described above, the RTR-HFP apparatus may provide candidate PRRs to the RTR simulator to find the optimal PRR through the optimal PRR search logic. The RTR-HFP apparatus may determine, based on the results (maximum temperature of the hydrogen tank (T_Tk_Max) and maximum mass flow rate of the charging line (m_FL_Max)), whether the PRR is optimal. The role of the RTR simulator in the RTR-HFP apparatus is to perform a hydrogen fueling simulation based on the PRR provided by the “optimal PRR search logic” to find T_Tk_Max and m_FL_Max. Thus, for RTR-HFP, the RTR simulator may periodically recalculate a new optimal PRR (the PRR that minimizes the fueling (hydrogen fueling) time while ensuring that the calculated T_Tk_Max and m_FL_Max do not exceed the limits when the target SOC is reached) and apply this value to the fuel supply process.

The RTR simulator explores or searches for the optimal PRR through iterative simulations. In the embedded Simple Model in the RTR-HFP apparats according to the present invention, the iterative simulations can be performed based on static data (e.g., TV and TLV) and dynamic data (e.g., pressure, temperature, and mass flow rate) obtained from the hydrogen dispenser 300 and the vehicle 100. To increase simulation speed in the Simple Model, the RTR simulator assumes the hydrogen fueling line is a straight pipe. To improve simulation accuracy for the physical model (real HRS), the Simple Model is fitted using the Rigorous model (H2FillS), with the fitting parameters being K_FL and d_FL.

Table 7 below presents a detailed flowchart for RTR-HFP. Referring to Table 6, this flowchart includes all the algorithms and thermodynamic equations required for the protocol to operate.

As described above in the description related to FIGS. 3 and 6, etc., the RTR-HFP apparatus calculates K_FL_RTR and d_FL_RTR by performing STEP 1 to STEP 5 described in Table 7. Thereafter, the RTR-HFP apparatus may complete the RTR simulator by replacing K_FL_RTR and d_FL_RTR in the fueling line of simple mode to replicate the results of the actual HRS (or real HRS). Thereafter, the RTR-HFP apparatus may search for a PRR that does not exceed T_Tk_Max (or T_Tk Lim) and m_FL_Max (or m_FL Lim). The RTR-HFP apparatus may provide the searched PRR to the hydrogen dispenser 300 (STEP 8). The RTR-HFP apparatus may repeatedly perform STEP 1 to STEP 8 at each time interval until the hydrogen fueling is completed. When the SOC of the CHSS tank reaches the target SOC (e.g., 95%), the fuel supply process is terminated.

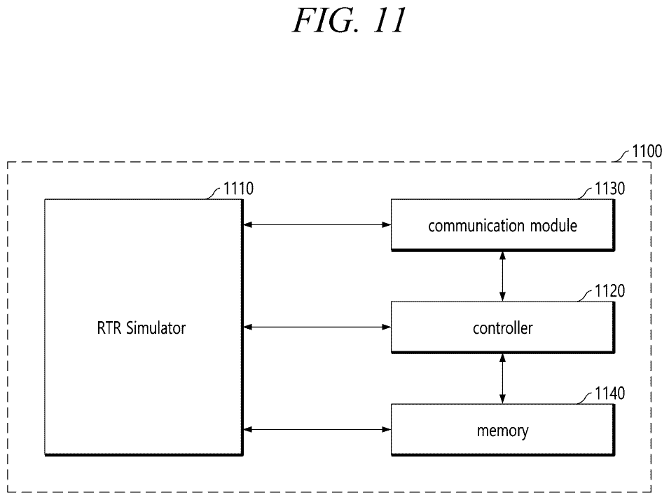

FIG. 11 is a block diagram illustrating the configuration of an RTR-HFP apparatus according to the present invention.

Referring to FIG. 11, the RTR-HFP apparatus 1100 may include an RTR simulator 1110 that performs “optimal PRR search logic,” a controller 1120, a communication module 1130, and a memory 1140.

The communication module 1130 may receive static and dynamic data from the vehicle and the hydrogen dispenser 300, and transmit necessary information (such as PRRs) to external sources, such as the hydrogen dispenser 300. For example, the communication module 1130 may obtain the corresponding information by receiving at least one of the following: the capacity of the largest hydrogen tank equipped for hydrogen fueling in a real case, the total capacity of the hydrogen tank, the supply fuel temperature of the fueling line, the supply fuel pressure, and the pressure of the hydrogen tank from the vehicle or the hydrogen dispenser 300.

The RTR simulator 1110 may extract, from a predefined lookup table, a first pressure loss coefficient corresponding to a pressure loss coefficient of a fueling line that satisfies a predetermined condition in a reference case based on the acquired information, and a second pressure loss coefficient corresponding to a pressure loss coefficient for SAE test configuration in H2FillS. The RTR simulator 1110 may calculate an average density in a fueling line based on Equation 1, etc. The RTR simulator 1110 may calculate a third pressure loss coefficient based on the calculated average density, the measured mass flow rate, and a pressure difference between the fuel supply pressure and the hydrogen tank pressure in the filling line. The RTR simulator 1110 may calculate a pressure loss coefficient of a virtual fueling line in the RTR simulator based on the extracted first pressure loss coefficient, second pressure loss coefficient, and the calculated third pressure loss coefficient.

In addition, the RTR simulator 1110 may extract the inner diameter of a reference fueling line that satisfies a predetermined condition in a reference case from a predefined lookup table, and may calculate the inner diameter of the virtual fueling line based on the pressure loss coefficient of the calculated virtual fueling line, the extracted first pressure loss coefficient, and the extracted inner diameter of the reference fueling line.

The RTR simulator 1110 may search for a PRR that does not exceed T_Tk_Max (or T_Tk Lim) and m_FL_Max (or m_FL Lim). The communication module 1130 can transmit the searched PRR to the hydrogen dispenser 300.

The controller 1120 can provide the initial PRR to the RTR simulator 1110 to simulate outcomes for the maximum temperature (T_Tk_Max) of the hydrogen tank and the maximum mass flow rate (m_FL_Max) of the charging line upon completion of charging. If the maximum temperature of the hydrogen tank (T_Tk_Max) and the maximum mass flow rate (m_FL_Max) of the fueling line do not meet the target values, the controller 1120 may provide the RTR simulator 1110 with a new candidate PRR for the RTR simulator 1110 to re-simulate. The controller 1120 can control the RTR simulator 1110 to repeat the simulation to search for the maximum temperature of the hydrogen tank (T_Tk_Max) and the maximum mass flow rate (m_FL_Max) of the fueling line until the target SOC is achieved, and to determine the applied PRR as the new PRR. As described above, the controller 1120 provides candidate PRRs to the RTR simulator 1110 to find the optimal PRR through optimal PRR search logic. The RTR simulator 1110 may determine whether the PRR is optimal based on the results (maximum temperature (T_Tk_Max) of the hydrogen tank and maximum mass flow rate (m_FL_Max) of the fueling line).

The controller 1120 may control the RTR simulator 1110 to periodically recalculate a new optimal PRR and apply this value to fuel supply. The memory 1140 can store various information, such as values calculated by the RTR simulator 1110, values provided by the controller 1120, various calculation results required for RTR-HFP execution, and information required for estimating various calculations. The RTR-HFP device (1100) operates as an external device separate from the hydrogen dispenser 300, but can also be installed and operated within the hydrogen dispenser 300.

As described above, the RTR-HFP according to the present invention is a protocol for the use phase, not the hydrogen fueling design phase, enabling rapid hydrogen fueling by calculating and recalculating the PRR at a desired frequency.

Since the RTR-HFP according to the present invention is a protocol for the use phase, not the hydrogen fueling design phase, it reduces many assumptions and limitations in calculating the PRR, enabling faster computation.

In the conventional protocol that applies a single average pressure ramp rate (APRR) from the beginning to the end of hydrogen fuel supply, it is impossible to adopt a high APRR due to a bottleneck that occurs in the initial stage of hydrogen fuel supply, and it is not easy to freely increase the number of lookup tables when calculating the APRR. However, in the case of the RTR-HFP according to the present invention, the hydrogen fueling protocol derives the pressure ramp rate (PRR) using real-time simulation in the application stage, thereby enabling the application of a higher PRR value in the latter stage of hydrogen fuel supply.

The apparatus or device described above may be implemented as hardware components, software components, and/or a combination of hardware components and software components. For example, the devices and components described in the embodiments may be implemented using one or more general-purpose computers or special-purpose computers, such as, for example, a processor, a controller, an arithmetic logic unit (ALU), a digital signal processor, a microcomputer, a field programmable gate array (FPGA), a programmable logic unit (PLU), a microprocessor, or any other device capable of executing instructions and responding to them. The processing device may execute an operating system (OS) and one or more software applications running on the operating system. Furthermore, the processing device may access, store, manipulate, process, and generate data in response to the execution of the software. For ease of understanding, the processing device is sometimes described as being used alone; however, one of ordinary skill in the art will recognize that the processing device may include multiple processing elements and/or multiple types of processing elements. For example, the processing device may include multiple processors or a processor and a controller. Other processing configurations, such as parallel processors, are also possible.

The software may include a computer program, code, instructions, or a combination of one or more of these, and may configure the processing device to perform a desired operation or, independently or collectively, command the processing device. The software and/or data may be permanently or temporarily embodied in any type of machine, component, physical device, virtual equipment, computer storage media or devices, or transmitted signal waves for interpretation by the processing device or for providing instructions or data to the processing device. The software may be distributed across networked computing devices and stored or executed in a distributed manner. The software and data may be stored on one or more computer-readable recording media.

The method according to the embodiment may be implemented in the form of program instructions that can be executed by various computer means and recorded on a computer-readable medium. The computer-readable medium may include program instructions, data files, data structures, and the like, either singly or in combination. The program instructions recorded on the medium may be specifically designed and configured for the embodiments, or may be known and available to those skilled in the art of computer software.

Examples of computer-readable recording media include magnetic media such as hard disks, floppy disks, and magnetic tapes; optical media such as CDROMs and DVDs; magneto-optical media such as floptical disks; and hardware devices specifically configured to store and execute program instructions, such as ROMS, RAMs, and flash memories.

Examples of program instructions include not only machine language codes generated by a compiler, but also high-level language codes that can be executed by a computer using an interpreter or the like. The hardware devices described above may be configured to operate as one or more software modules to perform the operations of the embodiments, and vice versa. The embodiments described above are combinations of components and features of the present invention in a specific form. Each component or feature should be considered optional unless otherwise explicitly stated. Each component or feature may be implemented without being combined with other components or features. Furthermore, it is also possible to combine some components and/or features to form an embodiment of the present invention. The order of operations described in the embodiments of the present invention may be changed.

Some components or features of one embodiment may be included in another embodiment or may be replaced with corresponding components or features of another embodiment. It is self-evident that claims that do not have an explicit citation relationship in the patent claims may be combined to form an embodiment or incorporated as new claims through post-application amendments. In the present invention, the RTR simulator 1110 and the controller 1120 may be implemented using hardware, firmware, software, or a combination thereof. When implementing embodiments of the present invention using hardware, ASICs (Application Specific Integrated Circuits), DSPs (Digital Signal Processors), DSPDs (Digital Signal Processing Devices), PLDs (Programmable Logic Devices), FPGAs (Field Programmable Gate Arrays), etc. configured to perform the present invention may be equipped in the RTR simulator 1110 and the controller 1120.

The present invention may also be implemented as a computer-readable recording medium recording a program for executing a method for preventing user information leakage during user authentication according to the present invention on a computer.

It will be apparent to those skilled in the art that the present invention may be embodied in other specific forms without departing from the essential characteristics thereof. Therefore, the above detailed description should not be construed as limiting in all respects, but rather as illustrative. The scope of the present invention should be determined by a reasonable interpretation of the appended claims, and all changes within the scope of equivalents thereof are intended to be included within the scope of the present invention.

1. A method for performing a hydrogen fueling simulation in a Real-Time Response Hydrogen fueling Protocol (RTR-HFP), the method comprising:
obtaining information on at least one of a capacity of a largest hydrogen tank equipped for hydrogen fueling in a real-case scenario, a total capacity of hydrogen tanks, a supply fuel temperature of a fueling line, a supply fuel pressure, and a pressure of a hydrogen tank;
extracting, from a predefined lookup table, a first pressure loss coefficient corresponding to a fueling line pressure loss coefficient that satisfies a predetermined condition in a reference case and a second pressure loss coefficient corresponding to a pressure loss coefficient for SAE test configuration in H2FillS, based on the obtained information;
calculating an average density in the fueling line;
calculating a third pressure loss coefficient based on the average density, a measured mass flow rate, and a pressure difference between a fuel supply pressure and a hydrogen tank pressure in the fueling line; and
calculating a pressure loss coefficient of a virtual fueling line in an RTR simulator based on the first pressure loss coefficient, second pressure loss coefficient, and the third pressure loss coefficient.

2. The method according to claim 1, further comprising:
extracting, from the predefined lookup table, an inner diameter of a reference fueling line that satisfies a predetermined condition in the reference case; and
calculating an inner diameter of the virtual fueling line based on the calculated pressure loss coefficient of the virtual fueling line, the extracted first pressure loss coefficient, and the extracted inner diameter of the reference fueling line.

3. The method according to claim 1, wherein the predefined lookup table includes:
a first type lookup table including pressure loss coefficients (K_FL_Ref) that satisfy a predetermined condition in the reference case according to an ambient air temperature and the supply fuel temperature for each capacity value of the largest hydrogen tank;
a second type lookup table including pressure loss coefficients (K_FL_H2F) for the SAE test configuration in the H2FillS; and
a third type lookup table including an inner diameter (d_FL_Ref) of the reference fueling line that satisfies the predetermined condition in the reference case.

4. The method according to claim 1, wherein the measured mass flow rate in the fueling line is measured by a flow meter installed in a hydrogen refueling station (HRS) in the real case.

5. The method according to claim 1, wherein the predetermined condition in the reference case is that a temperature of the hydrogen tank is 85° C. and a state of charge (SOC) of the hydrogen tank is 95% at a time of hydrogen fueling completion.

6. The method according to claim 1, wherein the average density of the fueling line is calculated based on:
a function of the fuel supply pressure and the supply fuel temperature; and
a function of the pressure of the hydrogen tank and the supply fuel temperature.

7. The method according to claim 1, wherein the pressure loss coefficient (K_FL_RTR) of the virtual fueling line is calculated based on a following equation 1 when the first pressure loss coefficient (K_FL_Ref) is greater than the third pressure loss coefficient (K_FL_HRS):
$$K\_FL \_RTR = K\_FL \_HRS \times ( \begin{matrix}K\_FL \_Ref & K\_FL \_H2F )\end{matrix} . \qquad [ Equation 1 ]$$

8. The method according to claim 1, wherein the pressure loss coefficient (K_FL_RTR) of the virtual fueling line is a equal to the third pressure loss coefficient (K_FL_HRS) when the first pressure loss coefficient (K_FL_Ref) is less than or equal to the third pressure loss coefficient.

9. The method according to claim 2, wherein the inner diameter (d_FL) of the virtual fueling line is calculated based on a following equation 2:
$$d\_FL \_RTR = d\_FL \_Ref * {( K\_FL \_Ref / K\_FL \_RTR )}^{0.25} \qquad [ Equation 2 ]$$
wherein d_FL_Ref is the inner diameter of the reference charging line, K_FL_RTR is the pressure loss coefficient of the virtual fueling line, and K_FL_Ref is the first reference pressure loss coefficient.

10. The method according to claim 1, wherein the RTR simulator searches for a pressure ramp rate (PRR) that does not exceed a predetermined limit condition based on the calculated pressure loss coefficient of the virtual fueling line.

11. Apparatus for performing a hydrogen fueling simulation according to a Real-Time Response Hydrogen fueling Protocol (RTR-HFP), the apparatus comprising:
a communication module configured to obtain information on at least one of a capacity of a largest hydrogen tank equipped for hydrogen fueling in a real-case scenario, a total capacity of hydrogen tanks, a supply fuel temperature of a fueling line, a supply fuel pressure, and a pressure of a hydrogen tank; and
an RTR simulator operably coupled to the communication module and configured to:
extract, from a predefined lookup table, a first pressure loss coefficient corresponding to a fueling line pressure loss coefficient that satisfies a predetermined condition in a reference case and a second pressure loss coefficient corresponding to a pressure loss coefficient for SAE test configuration in H2FillS, based on the obtained information;
calculate an average density in the fueling line;
calculate a third pressure loss coefficient based on the average density, a measured mass flow rate, and a pressure difference between a fuel supply pressure and a hydrogen tank pressure in the fueling line; and
calculate a pressure loss coefficient of a virtual fueling line based on the first pressure loss coefficient, second pressure loss coefficient, and the third pressure loss coefficient.

12. The apparatus according to claim 11, wherein the RTR simulator extracts, from the predefined lookup table, an inner diameter of a reference fueling line that satisfies a predetermined condition in the reference case, and calculates an inner diameter of the virtual fueling line based on the calculated pressure loss coefficient of the virtual fueling line, the extracted first pressure loss coefficient, and the extracted inner diameter of the reference fueling line.

13. The apparatus according to claim 11, wherein the RTR simulator searches for a pressure ramp rate (PRR) that does not exceed a predetermined limit condition based on the calculated pressure loss coefficient of the virtual fueling line.

14. The apparatus according to claim 13, further comprising:
a controller operably coupled to the communication module and the RTR simulator, and configured to provide information on candidate PRRs for searching the PRR to the RTR simulator.

15. A non-transitory computer-readable medium storing instructions that, when executed by a processor, cause the processor to perform the hydrogen fueling simulation method according to claim 1.

16. A non-transitory computer-readable medium storing instructions that, when executed by a processor, cause the processor to perform the hydrogen fueling simulation method according to claim 2.

17. A non-transitory computer-readable medium storing instructions that, when executed by a processor, cause the processor to perform the hydrogen fueling simulation method according to claim 3.

18. A non-transitory computer-readable medium storing instructions that, when executed by a processor, cause the processor to perform the hydrogen fueling simulation method according to claim 4.

19. A non-transitory computer-readable medium storing instructions that, when executed by a processor, cause the processor to perform the hydrogen fueling simulation method according to claim 5.

20. A non-transitory computer-readable medium storing instructions that, when executed by a processor, cause the processor to perform the hydrogen fueling simulation method according to claim 6.
